(19) United States
(12) Patent Application Publication
(10) Pub. No.: US 2024/0203704 A1
(43) Pub. Date: Jun. 20, 2024

(54) APPARATUS FOR TREATING SUBSTRATE

(71) Applicant: SEMES CO., LTD., Cheonan-si (KR)

(72) Inventors: Yoon Seok CHOI, Suwon-si (KR); Yun Sang KIM, Seongnam-si (KR); Han Lim KANG, Seoul (KR); Hyun Woo JO, Hwaseong-si (KR); Sang Jeong LEE, Hwaseong-si (KR); Youn Gun BONG, Suwon-si (KR)

(73) Assignee: SEMES CO., LTD., Cheonan-si (KR)

(21) Appl. No.: 18/526,489

(22) Filed: Dec. 1, 2023

(30) Foreign Application Priority Data
Dec. 15, 2022 (KR) 10-2022-0175917

(51) Int. Cl. H01J 37/32

(52) U.S. Cl. CPC H01J 37/32651; H01J 37/32522; H01J 37/3255; H01J 37/32568; H01J 2237/3348

(57) ABSTRACT

The inventive concept provides a substrate treating apparatus. The substrate treating apparatus includes an ion blocker dividing the inner space into a first space at a bottom side and a second space at a top side; a support unit configured to support a substrate at the first space; and a plasma source generating a plasma at the inner space, and wherein a plurality of passages are formed at the ion blocker for flowing a fluid from the second space to the first space, and the ion blocker is made of a dielectric substance, and an ion among an ion and a radical included in the plasma is captured while passing through the passage.

### CROSS-REFERENCE TO RELATED APPLICATIONS

A claim for priority under 35 U.S.C. § 119 is made to Korean Patent Application No. 10-2022-0175917 filed on Dec. 15, 2022, in the Korean Intellectual Property Office, the entire contents of which are hereby incorporated by reference.

### BACKGROUND

Embodiments of the inventive concept described herein relate to a substrate treating apparatus, more specifically, an apparatus for treating a substrate using a plasma.

A plasma refers to an ionized gas state consisting of ions, radicals, and electrons. The plasma is generated by a very high temperature, a strong electric field, or an RF Electromagnetic Field. The plasma and a substrate such as a wafer interact with each other to perform various semiconductor element manufacturing processes such as an etching process.

The plasma includes ions and radicals. An ion blocker blocks ions included in the plasma to supply neutral radicals to a treating space at which the substrate is positioned. In general, ion blockers are made of a metal and are grounded to capture ions. Since the ion blocker is made of a metal material, a laser or a microwave is reflected by the ion blocker and is not transmitted to the substrate. Accordingly, the ion blocker cannot be used in a process which requires transmitting a heat source to the substrate by transmitting the laser or the microwave to the substrate.

### SUMMARY

Embodiments of the inventive concept provide a substrate treating apparatus for solving the above-mentioned issues.

Embodiments of the inventive concept provide a substrate treating apparatus for efficiently treating a substrate.

Embodiments of the inventive concept provide a substrate treating apparatus for efficiently capturing ions included in a plasma, while transmitting a heat source to a substrate.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a chamber having an inner space; an ion blocker dividing the inner space into a first space at a bottom side and a second space at a top side; a support unit configured to support a substrate at the first space; and a plasma source generating a plasma at the inner space, and wherein a plurality of passages are formed at the ion blocker for flowing a fluid from the second space to the first space, and the ion blocker is made of a dielectric substance, and an ion among an ion and a radical included in the plasma is captured while passing through the passage.

In an embodiment, the passage is a through hole which penetrates a top-bottom surface of the ion blocker.

In an embodiment, the ion blocker is formed of a mesh structure having the passage.

In an embodiment, a plurality of the ion blockers are equipped, and the plurality of ion blockers are disposed in a top-down direction spaced apart from each other.

In an embodiment, a passage formed at any one ion blocker among the plurality of ion blockers does not overlap with a passage formed at an adjacent ion blocker when seen from above.

In an embodiment, the substrate treating apparatus further includes a heating unit configured to transmit a heat source to a substrate supported on the support unit, and wherein the heat source includes a light, a microwave, or a laser.

In an embodiment, a plasma source includes a coil surrounding an outer wall of the chamber and which applies a high frequency power, and the heating unit is positioned at a top end of the chamber and transmits the heat source toward the ion blocker.

In an embodiment, the plasma source includes an electrode plate which is positioned at a top end of the chamber and applies a high frequency power, and the support unit is grounded, and the heating unit is positioned at a top side of the electrode plate.

In an embodiment, the electrode plate is made of a material including an Indium Tin Oxide (ITO) which lets the heat source pass through.

In an embodiment, a guide rail is installed at an inner sidewall of the chamber, and a driving unit is installed at the ion blocker, and the driving unit moves along the guide rail to change a position of the ion blocker.

In an embodiment, as an aspect ratio of a thickness of the ion blocker and a width of the passage increases, an amount of the ion captured by the ion blocker increases.

In an embodiment, as an interval between the plurality of ion blockers decreases, an amount of the ion which is captured by the ion blocker increases.

The inventive concept provides a substrate treating apparatus. The substrate treating apparatus includes an ion blocker which captures an ion included in a plasma; and a support unit disposed at a bottom side of the ion blocker and configured to support a substrate, and wherein the ion blocker is made of a dielectric substance.

In an embodiment, a plurality of through holes are formed at the ion blocker for flowing a fluid between a top space of the ion blocker and a bottom space of the ion blocker.

In an embodiment, a plurality of ion blockers are equipped, and the plurality of ion blockers are disposed in a top-down direction spaced apart from each other.

In an embodiment, a through hole formed at any one ion blocker among the plurality of ion blockers does not overlap with a through hole formed at an adjacent ion blocker when seen from above.

In an embodiment, the ion blocker is formed of a mesh structure.

In an embodiment, the substrate treating apparatus further includes a heat unit configured to transmit a heat source to a substrate supported on the support unit.

In an embodiment, the heating unit includes a lamp, a laser optical system, or a microwave generator.

The inventive concept provides a substrate treating apparatus. The substrate treating apparatus includes a chamber having an inner space; an ion blocker dividing the inner space into a first space at a bottom side and a second space at a top side; a support unit configured to support a substrate at the first space; and a gas supply unit configured to supply a gas excited to a plasma at the second space; a plasma source generating the plasma at the first space and/or the second space; and a heating source passing through the ion blocker and transmitting a heat source to a substrate supported on the support unit, and wherein the ion blocker is formed of a dielectric substance, and a plurality of passages are formed at the ion blocker for flowing a fluid, and an ion among an ion and a radical included in the plasma are captured while passing through the passage, and the heating source passes through the ion blocker to be transmitted to the substrate supported on the support unit.

According to an embodiment of the inventive concept, a substrate may be efficiently treated.

According to an embodiment of the inventive concept, ions included in a plasma may be efficiently captured while transmitting a heat source to a substrate.

According to an embodiment of the inventive concept, a ratio of ions and radicals which act on a substrate may be efficiently adjusted.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a perspective view schematically illustrating an ion blocker according to an embodiment.

FIG. 3 schematically illustrates a state of treating a substrate in the substrate treating apparatus of FIG. 1.

FIG. 4 is a cross-sectional view schematically illustrating the substrate treating apparatus according to another embodiment.

FIG. 5 schematically illustrates a state of treating the substrate in the substrate treating apparatus of FIG. 4.

FIG. 6 is a perspective view schematically illustrating the ion blocker according to another embodiment.

FIG. 7 is a cross-sectional view schematically illustrating the substrate treating apparatus according to another embodiment.

FIG. 8 schematically illustrates a state of treating the substrate in the substrate treating apparatus of FIG. 7.

FIG. 9 is a cross-sectional view schematically illustrating the substrate treating apparatus according to another embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

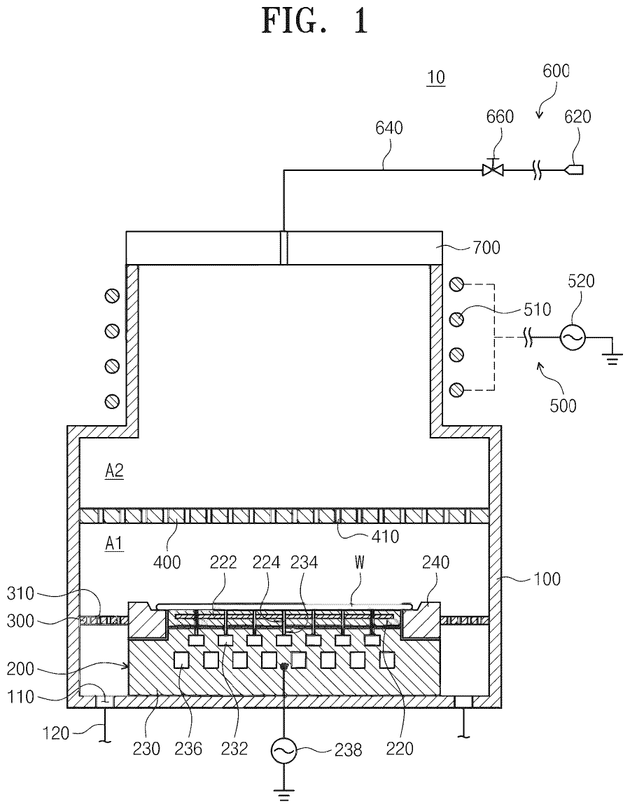

FIG. 1 is a cross-sectional view schematically illustrating a substrate treating apparatus according to an embodiment.

The substrate treating apparatus 10 according to an embodiment treats a substrate W using a plasma. For example, the substrate treating apparatus 10 can perform processes such as an etching process to remove a thin film formed on the substrate W using the plasma, an ashing process to remove a photoresist film, a deposition process to form a thin film on the substrate W, an ALD (Atomic Layer Deposition) process to deposit an atomic layer on the substrate W, an ALE process to etch the atomic layer on the substrate W, or a dry cleaning process to remove a foreign substance attached to the substrate. In addition, the substrate treating apparatus 10 can perform a surface modification process on a surface of the substrate W using the plasma. However, it is not limited to the above-described example, and the substrate treating apparatus 10 may be applied equally or similarly to various apparatuses which treat a substrate W such as a wafer using the plasma.

The substrate treating apparatus 10 may include a chamber 100, a support unit 200, an ion blocker 400, a plasma source 500, a gas supply unit 600, and a heating unit 700.

The chamber 100 may have a substantially cylindrical shape. A top portion of the chamber 100 and a bottom portion of the chamber 100 may be stepped. More specifically, a top diameter of the chamber 100 may be smaller than a bottom diameter of the chamber 100. However, the inventive concept is not limited thereto, and the top and bottom diameters of the chamber 100 may all be the same. A top end of the chamber 100 may be opened. An open top end of the chamber 100 may be sealed from the outside by a heating unit 700 to be described later.

The chamber 100 has an inner space. The inner space may be divided into a first space A1 at a bottom side and a second space A2 at a top side. The first space A1 is defined as a space formed by combining the chamber 100 and the ion blocker 400 to be described later. The second space A2 is defined as a space formed by a combination of the chamber 100, the ion blocker 400, and the heating unit 700 described later. The first space A1 functions as a space for treating the substrate W. In addition, the second space A2 functions as a space in which the plasma is formed.

An opening (not shown) through which the substrate W is taken in and out is formed on a sidewall of the chamber 100. The opening (not shown) may be selectively opened and closed by a door assembly which is not shown. An inner sidewall of the chamber 100 may be coated with a material capable of preventing an etching by a plasma generated in the first space A1. In addition, the chamber 100 may be grounded.

An exhaust hole 110 is formed at a bottom of the chamber 100. The exhaust hole 110 is connected to an exhaust line 120. A pump which is not shown may be installed in the exhaust line 120. The pump (not shown) adjusts a pressure of the first space A1 by applying a negative pressure to the exhaust line 120 to exhaust an atmosphere of the first space A1. In addition, the pump (not shown) discharges the foreign substances remaining in the first space A1 to an outside of the first space A1. The pump (not shown) according to an embodiment may be any one of known pumps applying the negative pressure.

The support unit 200 is positioned in the first space A1. The support unit 200 is disposed below the ion blocker 400 to be described later to face the ion blocker 400. The support unit 200 supports the substrate W. Unlike FIG. 1, the support unit 200 may be positioned to be spaced apart from the bottom of the chamber 100 by a predetermined distance in an upward direction. For example, it may be positioned to be spaced apart from the bottom of the chamber 100 through a connection unit (not shown) connected to the sidewall of the chamber 100.

The support unit 200 according to an embodiment may be an electrostatic chuck which chucks the substrate W using an electrostatic force. Unlike this, the support unit 200 may support the substrate W in various ways such as a vacuum adsorption or a mechanical clamping. Hereinafter, for convenience of understanding, a case in which the support unit 200 is an electrostatic chuck will be described as an example.

The support unit 200 may include a first plate 220 and a second plate 230. The first plate 220 may be a disk-shaped dielectric substance. The substrate W may be disposed on a top surface of the first plate 220. According to an embodiment, the top surface of the first plate 220 may have a diameter smaller than that of the substrate W. Accordingly, if the substrate W is placed on the top surface of the first plate 220, an edge region of the substrate W may be positioned outside the first plate 220.

An electrostatic electrode 222 is disposed within the first plate 220. The electrostatic electrode 222 is electrically connected to a power source which is not shown. According to an embodiment, the power source (not shown) may be a DC power source. An electrostatic force is applied between the electrostatic electrode 222 and the substrate W by a direct current flowing through the electrostatic electrode 222. Accordingly, the substrate W is adsorbed to the first plate 220. In addition, a heater (not shown) for adjusting a temperature of the first plate 220 may be further disposed within the first plate 220. If a heater (not shown) is disposed within the first plate 220, the heater (not shown) may be disposed below the electrostatic electrode 222.

At least one first fluid channel 224 may be formed within the first plate 220. The first fluid channel 224 may be formed from the top surface of the first plate 220 to a bottom surface of the first plate 220. The first fluid channel 224 is connected to a second fluid channel 234 to be described later. The first fluid channel 224 functions as a passage through which a heat transfer medium is supplied to a bottom surface of the substrate W. The heat transfer medium will be described later.

The second plate 230 is positioned below the first plate 220. According to an embodiment, the second plate 230 may have a disk shape. A top surface of the second plate 230 may be formed to be stepped so that a central region thereof is positioned higher than an edge region. A center region of a top portion of the second plate 230 may have a region corresponding to the bottom surface of the first plate 220. A center region of the top surface of the second plate 230 may be adhered to the bottom surface of the first plate 220. A ring member 240 to be described later may be positioned above an edge region of the second plate 230.

A first circulation fluid channel 232, a second fluid channel 234, and a second circulation fluid channel 236 may be positioned within the second plate 230.

The first circulation fluid channel 232 may be a passage through which a heat transfer medium circulates. The heat transfer medium may include an inert gas. For example, the heat transfer medium may include a helium gas. While performing a plasma treatment on the substrate W, the heat transfer medium may be a gas supplied to the bottom surface of the substrate W to eliminate a temperature imbalance of the substrate W. In the above-described example, the heat transfer medium has been described as a gas, but it may be a fluid.

The first circulation fluid channel 232 may have a spiral shape. However, the inventive concept is not limited thereto, and the first circulation fluid channel 232 may share a same center with each other, but may be provided in a ring shape having a different radius.

The second fluid channel 234 is connected to the first circulation fluid channel 232. In addition, the second fluid channel 234 is connected to the first fluid channel 224. That is, the second fluid channel 234 fluidly communicates the first circulation fluid channel 232 with the first fluid channel 224. The heat transfer medium is supplied to the bottom of the substrate W through the first circulation fluid channel 232, the second fluid channel 234, and the first fluid channel 224.

The second circulation fluid channel 236 may be a passage through which a cooling fluid circulates. The cooling fluid may adjust a temperature of the second plate 230 while flowing within the second circulation fluid channel 236. Accordingly, a temperature of the substrate W may be adjusted via the second plate 230. According to an embodiment, the second circulation fluid channel 236 may be disposed below the first circulation fluid channel 232. The second circulation fluid channel 236 may have the same or similar shape as the first circulation fluid channel 232 described above. Accordingly, a detailed description of a shape of the second circulation fluid channel 236 will be omitted.

A bottom power source 238 may be electrically connected to the second plate 230 according to an embodiment. The bottom power source 238 may apply an RF power or a bias power to the second plate 230. A power applied to the second plate 230 may improve an input property of the plasma formed in the second space A2 with respect to the substrate W.

According to an embodiment, the ring member 240 may be a focus ring having a ring shape. The ring member 240 is disposed along a circumference of the first plate 220. In addition, the ring member 240 may be disposed at a top portion of an edge region of the first plate 220. A top surface of the ring member 240 may be formed to be stepped. For example, an inner portion of the top surface of the ring member 240 may be positioned at a lower height than an outer portion of the top surface. According to an embodiment, the inner portion of the top surface of the ring member 240 may be positioned at the same height as the top surface of the first plate 220. In addition, the inner portion of the top surface of the ring member 240 can support a bottom surface of an edge region of the substrate W positioned outside the first plate 220. An outer portion of the top surface of the ring member 240 may surround a side surface of the substrate W.

The exhaust baffle 300 is positioned in the first space A1. The exhaust baffle 300 is positioned above the exhaust hole 110. In addition, when viewed from above, the exhaust baffle 300 is positioned to overlap the exhaust hole 110. In addition, the exhaust baffle 300 is positioned between the inner sidewall of the chamber 100 and the support unit 200. The exhaust baffle 300 may have a substantially ring shape. At least one baffle hole 310 is formed in the exhaust baffle 300. The baffle hole 310 may penetrate a top surface and a bottom surface of the exhaust baffle 300. A gas remaining in the first space A1 and foreign substances generated in a process of treating the substrate W with the plasma are discharged to the exhaust hole 110 through the baffle hole 310.

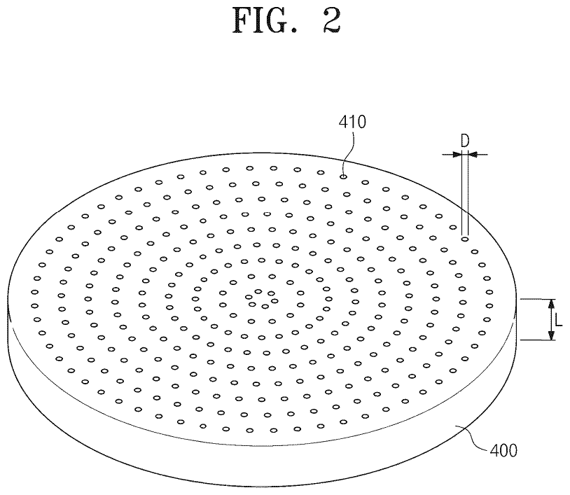

FIG. 2 is a perspective view schematically illustrating an ion blocker according to an embodiment.

Hereinafter, the ion blocker according to an embodiment will be described with reference to FIG. 1 and FIG. 2.

The ion blocker 400 is disposed above the support unit 200 to face a substrate W supported by the support unit 200. In addition, the ion blocker 400 is disposed under the heating unit 700 to be described later. The ion blocker 400 may be fixedly installed on the inner sidewall of the chamber 100 by a fixing means which is not shown.

The ion blocker 400 may have a disk shape having a constant thickness. A passage is formed in the ion blocker 400. The passage functions as a path through which a fluid flows between the first space A1 and the second space A2. More preferably, the passage according to an embodiment functions as a path at which the fluid flows from the second space A2 to the first space A1, while interfering with a flow of the fluid from the first space A1 to the second space A2.

The passage according to an embodiment may be a through hole 410. A plurality of through holes 410 are formed in the ion blocker 400. More specifically, the plurality of through holes 410 may be arranged in a plurality of rows along a circumferential direction of the ion blocker 400. In addition, the plurality of through holes 410 are arranged to be spaced apart from each other.

According to an embodiment, a ratio of a width (diameter, D) of the through holes 410 to a thickness L of the ion blocker 400 may be defined as an aspect ratio. The aspect ratio can be changed according to a recipe. More specifically, at least one of the width D of the through holes 410 and the thickness L of the ion blocker 400 may be changed according to the recipe. A detailed description of this will be described later.

The ion blocker 400 may be made of a material capable of transmitting a wavelength. For example, the ion blocker 400 may be made of a material capable of transmitting light, a laser, or a microwave having a wavelength in a specific range. In addition, the ion blocker 400 may be made of a material having a plasma resistance. The ion blocker 400 according to an embodiment may be formed of a dielectric substance. For example, a material of the ion blocker 400 may include a quartz or a ceramic. In addition, the ion blocker 400 may exclude a metal material.

The plasma source 500 may generate the plasma in the second space A2. More specifically, the plasma source 500 may form an electronic field in the second space A2 to excite a gas supplied to the second space A2. The plasma source 500 may include an antenna 510 and a high frequency power source 520.

The antenna 510 may include a coil in a spiral shape wound a plurality of times. The coil may be disposed to surround an outer wall of the top portion of the chamber 100. A high frequency power source 520 may be positioned outside the chamber 100. According to an embodiment, the high frequency power source 520 may be an RF power source. An end of a power line to which the high-frequency power source 520 is connected is connected to the coil to apply the high-frequency power to the coil. In addition, the end of the power line to which the high-frequency power source 520 is connected may be grounded. The coil may receive the high frequency power from the high frequency power source 520 to induce a time-varying electric field in the second space A2. Accordingly, the gas supplied to the second space A2 by a gas supply unit 600 to be described later may be excited as the plasma.

The gas supply unit 600 supplies the gas to the second space A2. The gas supplied to the second space A2 may be the gas excited by the plasma. In addition, the gas supplied to the second space A2 may be a gas contributing to an ignition. In addition, the gas supplied to the second space A2 may be a carrier gas. In some other embodiments, the gas supply unit 600 may further supply a reaction gas to the first space A1. The reaction gas may be a gas which reacts with a radical supplied to the first space A1 to form an etchant.

The gas supply unit 600 may include a gas supply source 620, a gas line 640, and a valve 660. The gas supply source 620 stores a gas. An end of the gas line 640 may be connected to the gas supply source 620, and the other end thereof may be installed to communicate with the second space A2. FIG. 1 illustrates that the other end of the gas line 640 communicates with the second space A2 via a heating unit 700 to be described later, but the installation position of the other end of the gas line 640 can be various modified. For example, the other end of the gas line 640 may communicate with the second space A2 via the sidewall of the chamber 100. The valve 660 is installed in the gas line 640. The valve 660 may be an opening/closing valve and/or a flow control valve.

The heating unit 700 may be disposed at an open top end of the chamber 100. The heating unit 700 is combined with the chamber 100 to seal the second space A2 from the outside. The heating unit 700 transmits a heat source to a substrate W supported by the support unit 200. More specifically, the heat source passes through the ion blocker 400 and is transmitted to the substrate W.

The heating unit 700 may include a lamp, a laser optical system, or a microwave generator. For example, the lamp may include a flash lamp, an IR lamp, and a near-infrared lamp. If the heating unit 700 is provided as a lamp, the heating unit 700 transmits a light, which is the heat source, to the substrate W. In addition, if the heating unit 700 is provided as a laser optical system, the heating unit 700 transmits a laser, which is the heat source, to the substrate W. In addition, if the heating unit 700 is a microwave generator, the heating unit 700 may consist of an antenna and a waveguide which applies microwaves. In this case, the heating unit 700 transmits the microwave, which is the heat source, to the substrate W.

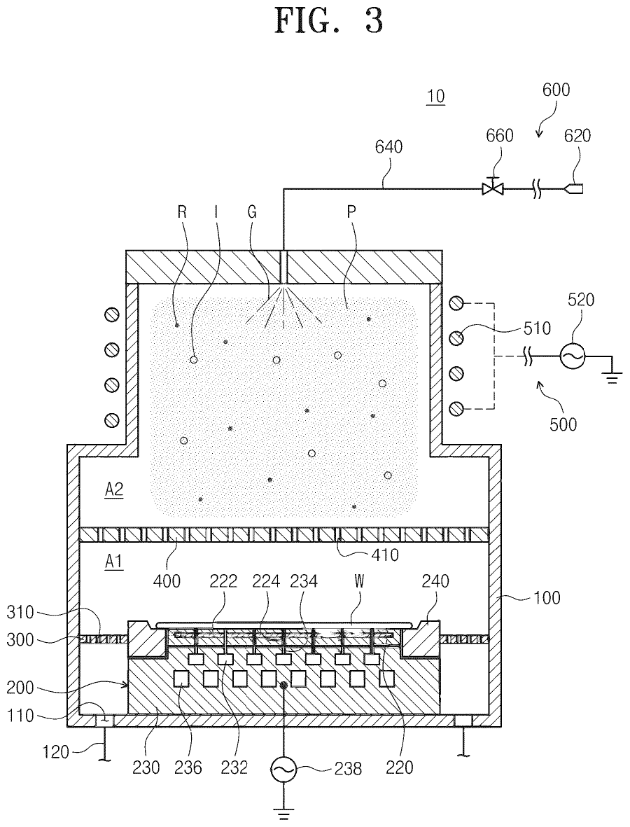

FIG. 3 schematically illustrates a state of treating a substrate in the substrate treating apparatus of FIG. 1.

If the high-frequency power source 520 applies the high-frequency power to the coil, an electric field is formed in the second space A2. In addition, the gas supply unit 600 supplies the gas G to the second space A2. The gas G supplied to the second space A2 is excited to a plasma P state by an electric field formed in the second space A2. Accordingly, the plasma P is formed in the second space A2. The plasma P includes ions I and radicals R. The plasma P flows from the second space A2 to the first space A1 through the through hole 410 formed in the ion blocker 400. Most of the ions I among the ions I and radicals R included in the plasma P are captured (blocked) by the ion blocker 400 as the plasma P passes through the through hole 410. The radicals R may act on the substrate W positioned in the first space A1 to treat the substrate W.

In addition, the aspect ratio described above may be changed depending on a type of process performed in the substrate treating apparatus 10 or a recipe according to the process. For example, when treating the substrate W by creating a high ratio of radicals among the ions and radicals in the first space A1, the aspect ratio can be greatly changed. As an embodiment of greatly changing the aspect ratio, a thickness of the ion blocker 400 may be greatly changed. In addition, a width (diameter) of the through holes 410 may be reduced. In addition, the thickness of the ion blocker 400 may be greatly changed, and the width (diameter) of the through holes 410 may be reduced. The larger the thickness of the ion blocker 400 and the smaller the width (diameter) of the through hole 410 is, the more ions I can be captured in the process of passing through the through hole 410. In order to make the ratio of the radicals in the first space A1 smaller by changing the aspect ratio to a small size, the thickness of the ion blocker 400 may be reduced and/or the width (diameter) of the through holes 410 may be greatly changed by a mechanism contrary to the above-mentioned example

In addition, if the substrate treating apparatus 10 performs a process of transmitting a heat source to the substrate W (e.g., an atomic layer etching ALE process, ALE), the heating unit 700 transmits the heat source to the substrate W. As described above, since the plate 500 and the ion blocker 400 are made of a material capable of passing through a certain wavelength, the heat source can be smoothly transmitted to the substrate W.

Hereinafter, the substrate treating apparatus according to another embodiment will be described. The substrate treating apparatus described below and the components included therein are mostly the same as or similar to the embodiment described with reference to FIG. 1 to FIG. 3 in addition to the case of additional description. Accordingly, the description of the overlapping content will be omitted below.

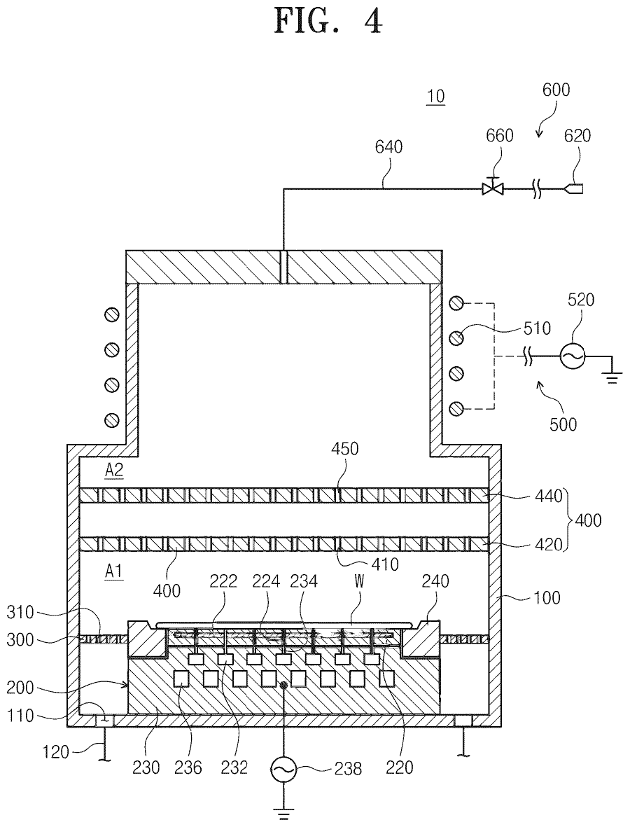

FIG. 4 is a cross-sectional view schematically illustrating the substrate treating apparatus according to another embodiment.

The ion blocker 400 may include a first ion blocker 420 and a second ion blocker 440. The first ion blocker 420 is disposed below the second ion blocker 440. In addition, the second ion blocker 440 is disposed between the first ion blocker 420 and the heating unit 700. In addition, the first ion blocker 420 and the second ion blocker 440 are disposed to face each other. The first ion blocker 420 and the second ion blocker 440 are disposed to be spaced apart from each other by a predetermined distance. Although FIG. 4 illustrates the first ion blocker 420 and the second ion blocker 440 separated by a considerable distance, this is only for convenience of understanding. The narrower a distance between the first ion blocker 420 and the second ion blocker 440 according to an embodiment, the higher a capture rate of ions included in the plasma is.

The above-described first space A1 may be formed by a combination of the first ion blocker 420 and the chamber 100. That is, the first space A1 is defined as a bottom space of the first ion blocker 420. In addition, the second space A2 may be formed by a combination of the second ion blocker 440, the heating unit 700, and the chamber 100. That is, the second space A2 is defined as a top space of the second ion blocker 440.

A plurality of first through holes 430 are formed in the first ion blocker 420. The plurality of first through holes 430 may be formed in a plurality of rows along a circumferential direction of the first ion blocker 420. In addition, the first through holes 430 may be arranged to be spaced apart from each other. A plurality of second through holes 450 are formed in the second ion blocker 440. The plurality of second through holes 450 may be formed in a plurality of rows along a circumferential direction of the second ion blocker 440. In addition, the second through holes 450 may be arranged to be spaced apart from each other. In addition, when viewed from above, the second through holes 450 are disposed to not overlap with the first through holes 430.

A passage is formed in each of the first ion blocker 420 and the second ion blocker 440. The passage formed in the first ion blocker 420 functions as a path through which a fluid flows between a space between the first ion blocker 420 and the second ion blocker 440 and the first space A1. In addition, the passage formed in the second ion blocker 440 functions as a path through which a fluid flows between the space between the first ion blocker 420 and the second ion blocker 440 and the second space A2.

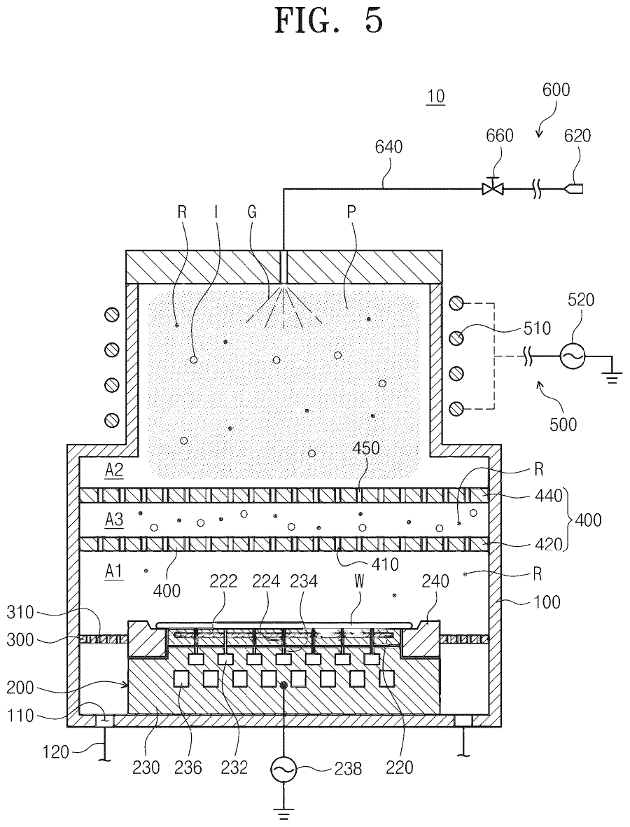

FIG. 5 schematically illustrates a state of treating a substrate in the substrate treating apparatus of FIG. 4.

The plasma P formed in the second space A2 passes through the first through hole 430 and flows into the space between the first ion blocker 420 and the second ion blocker 440. In this process, most of the ions I included in the plasma P are firstly captured by the first ion blocker 420. However, some ions I included in the plasma P flow into the space between the first ion blocker 420 and the second ion blocker 440. Some ions I which have flowed into the space between are secondly captured in a process of passing through the second through hole 450. In addition, the first through hole 430 and the second through hole 450 are arranged to not overlap each other when viewed from above, so some ions I can be more efficiently captured by the second ion blocker 440.

As described above, since the ion blocker 400 according to an embodiment excludes a metal material, an ion I capture rate may be lower than that of an ion blocker made of a general metal material. Thus, according to an embodiment of the inventive concept described above, heat sources can be pass through, but ions I can be efficiently captured by supplementing for weaknesses of the ion blocker 400 according to an embodiment at which the capture rate of ions I may be low.

In the aforementioned example, it has been described that the ion blocker 400 includes the first ion blocker 420 and the second ion blocker 440, but the inventive concept is not limited to it. For example, the ion blockers 400 may be provided in a plurality in a number of three or more, and each of the plurality of ion blockers may be disposed to be spaced apart from each other in the vertical direction. In addition, a through hole formed in any one ion blocker among the plurality of ion blockers may have a structure which does not overlap with a through hole formed in an adjacent ion blocker when viewed from above.

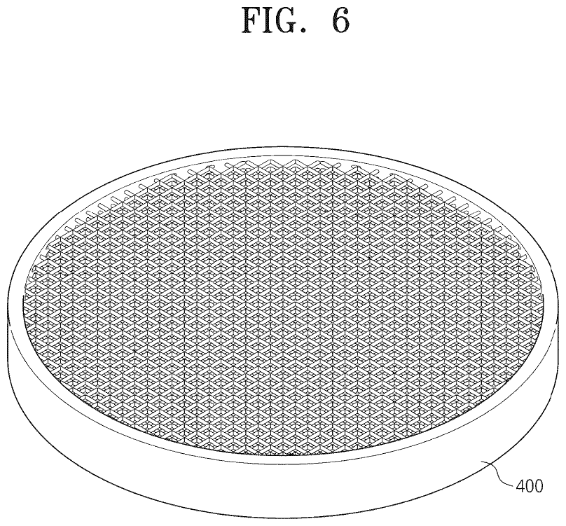

FIG. 6 is a perspective view schematically illustrating the ion blocker according to another embodiment.

Referring to FIG. 6, the ion blocker 400 according to an embodiment of the inventive concept may have a mesh structure. That is, the ion blocker 400 according to an embodiment may have a mesh structure having a passage. In addition, the mesh structure according to an embodiment may be made of a glass-fiber material. Accordingly, the ion blocker 400 according to an embodiment may transmit a heat source.

The passage may perform a same function as the passage described above and may be provided in a fine size. In addition, the passage can pass through a fluid (e.g., a plasma). In FIG. 6, the ion blocker 400 is illustrated to have a mesh structure having a rectangular shape, but is not limited thereto. For example, the ion blocker 400 may have a mesh structure in which polygons such as triangles and hexagons are repeatedly formed.

In addition, the ion blocker 400 according to an embodiment may have a structure in which the aforementioned mesh structure is stacked in multiple layers. As a number of stacking layers of the mesh structure increases, the capture rate of ions included in the plasma may increase.

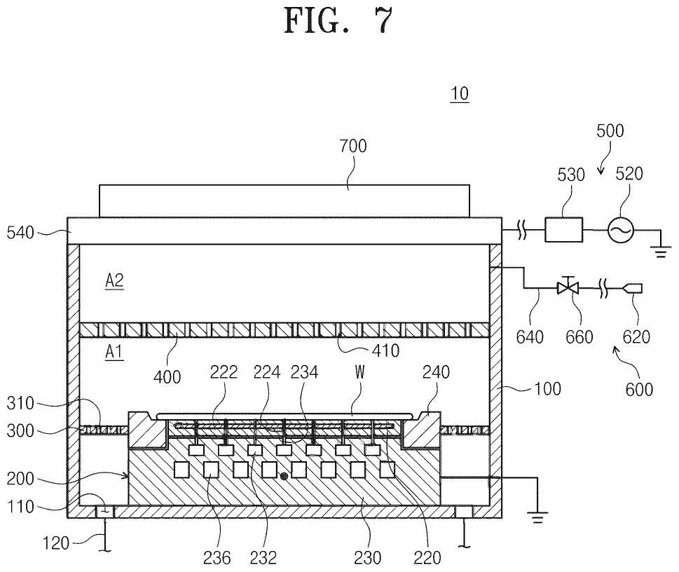

FIG. 7 is a cross-sectional view schematically illustrating the substrate treating apparatus according to another embodiment.

Referring to FIG. 7, the chamber 100 according to an embodiment may have a substantially cylindrical shape. In addition, the top end of the chamber 100 may be opened. In addition, the support unit 200 according to an embodiment may be grounded. More specifically, the second plate 230 may be grounded. In addition, the heating unit 700 may be disposed above the electrode plate 540 to be described later. In addition, the other end of the gas line 640 according to an embodiment may be connected to the sidewall of the chamber 100. However, the inventive concept is not limited thereto, and the installation position of the other end of the gas line 640 may be variously modified.

In addition, the plasma source 500 according to an embodiment may include a high frequency power source 520, an impedance matcher 530, and an electrode plate 540.

The high-frequency power source 520 is electrically connected to the electrode plate 540 to be described later. Accordingly, the high frequency power source 520 applies the high frequency power to the electrode plate 540. Accordingly, the electrode plate 540 may function as a top electrode which generates a plasma in the inner space of the chamber 100. In addition, support unit 200 which is grounded may function as a bottom electrode which generates a plasma in the inner space of the chamber 100. The impedance matcher 530 may be installed between the high frequency power source 520 and the electrode plate 540. The impedance matcher 530 matches an impedance of the high frequency power applied to the electrode plate 540.

The electrode plate 540 may have a substantially disk shape. The electrode plate 540 is disposed at the open top end of the chamber 100. In addition, the electrode plate 540 is disposed above the ion blocker 400. In addition, the electrode plate 540 is disposed under the heating unit 700. The electrode plate 540 is positioned to face the ion blocker 400.

The electrode plate 540 in accordance with an embodiment may be a transparent plate capable of transmitting the heat source transmitted from the heating unit 700. More specifically, the electrode plate 540 may be a transparent electrode made of an indium tin oxide (ITO) material composed of an indium oxide and a tin oxide. In addition, the electrode plate 540 may be any one of an AZO, an FTO, an ATO, an SnO₂, a ZnO, an IrO₂, a graphene, a metal nanowire, or a CNT, or may be formed by a mixture combination of one or more, or may be formed of a multiple combination.

The inner space of the chamber 100 may be divided into the first space A1 and the second space A2 described above. As described above, the first space A1 may mean a bottom space with respect to the ion blocker 400. In addition, the second space A2 may mean a top space with respect to the ion blocker 400. According to the above example, the electrode plate 540 functions as a top electrode which generates the plasma, and the support unit 200 functions as a bottom electrode. Accordingly, the plasma may be generated in each of the first space A1 and the second space A2.

Accordingly, the bottom portion of the electrode plate 540 exposed to the second space A2 may be coated with a plasma-resistant and a corrosion-resistant material with a transparency. For example, the bottom portion of the electrode plate 540 may be at least one of a Y₂O₃, a YSZ (Yttria-stabilized zirconia, ZrO₂/Y₂O₃), a YAG (Yttrium aluminum garnet, Y₃Al₅O₁₂), an Al₂O₃, a Cr₂O₃, an Nb₂O₅, and an Si₃N₃. Also, it may be provided as a combination thereof. Unlike the above-described example, the electrode plate 540 may have a structure in which a plurality of plates are stacked, a top plate may be a transparent electrode formed of a material such as an ITO, and a bottom plate may be formed of a material such as a Y₂O₃.

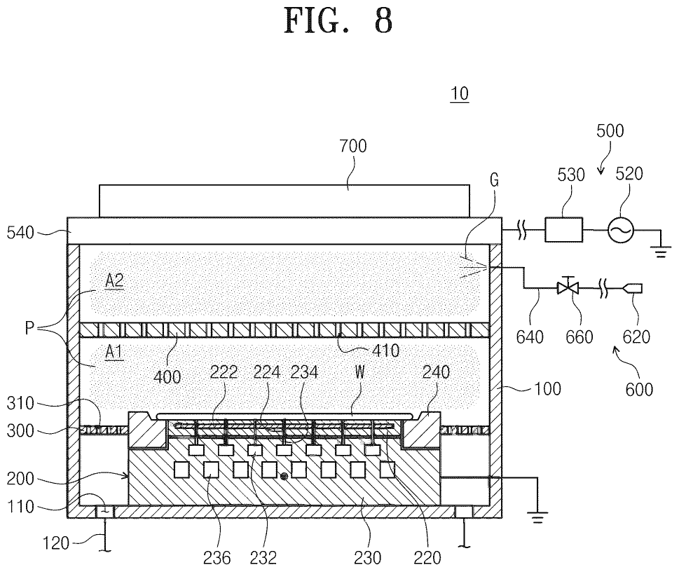

FIG. 8 schematically illustrates a state of treating the substrate in the substrate treating apparatus of FIG. 7.

Referring to FIG. 8, if the high-frequency power is applied to the electrode plate 540, an electric field is formed in the space between the support unit and the electrode plate 540. For example, the electric field is formed in both the first space A1 and the second space A2. In addition, a gas G supplied to the second space A2 flows to the second space A2 and the first space A1. In this process, the plasma P is generated in both the first space A1 and the second space A2.

Most of the ions included in the plasma P generated in the second space A2 among the first space A1 and the second space A2 are captured in a process of passing through the through hole 410. Unlike this, ions included in the plasma P generated in the second space A2 act on the substrate W as they are. That is, a ratio of ions and radicals acting to the substrate W may vary depending on an installation position of the ion blocker 400.

For example, if a size of the second space A2 increases relatively by installing the ion blocker 400 relatively close to the substrate W, a probability that ions included in the plasma P generated in the second space A2 are captured by the ion blocker 400 increases. Accordingly, a ratio of radicals acting to the substrate W may be relatively increased.

In contrast, if the size of the second space A2 decreases relatively by installing the ion blocker 400 relatively far from the substrate W, the probability that ions included in the plasma P generated in the second space A2 are captured in the ion blocker 400 decreases. Accordingly, the ratio of radicals acting to the substrate W may be relatively reduced.

That is, according to the above-described embodiment, it is possible to efficiently adjust the ratio of radicals and ions acting to the substrate W by changing the installation position of the ion blocker 400.

In addition, if it is necessary to transmit the heat source to the substrate W in the process of treating the substrate W, the heating unit 700 transmits the heat source toward the electrode plate 540. The heat source transmitted to the electrode plate 540 passes through the electrode plate 540 and is transmitted to the second space A2 due to a material of the electrode plate 540. The heat source transmitted to the second space A2 may pass through the ion blocker 400 and be transmitted to the substrate W positioned in the first space A1.

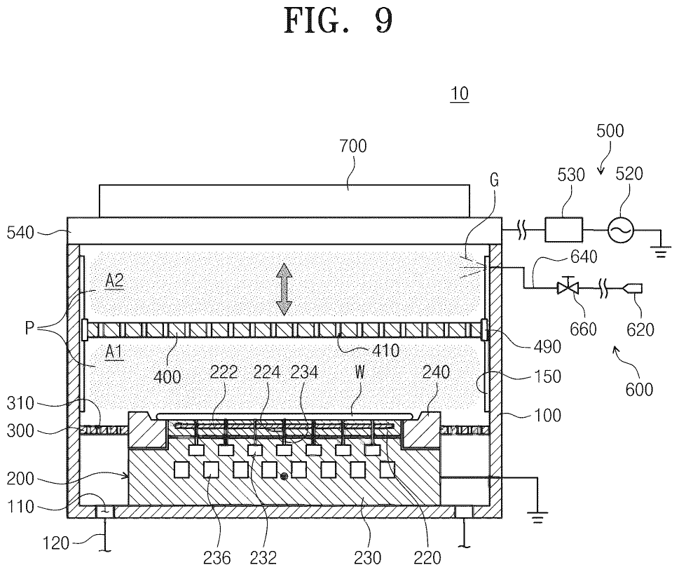

FIG. 9 is a cross-sectional view schematically illustrating the substrate treating apparatus according to another embodiment.

The substrate treating apparatus 10 according to the embodiment described in FIG. 9 is mostly the same or similar to the substrate treating apparatus described in FIG. 7 and FIG. 8, except for additional explanations.

Referring to FIG. 9, a guide rail 150 may be installed on the inner sidewall of the chamber 100 according to an embodiment. The guide rail 150 may have a vertical lengthwise direction. A top end of the guide rail 150 may be positioned below the electrode plate 540, and the bottom end of the guide rail 150 may be positioned above the baffle 300.

The driving unit 490 may be coupled to the ion blocker 400. In addition, the driving unit 490 may be coupled to both ends of the ion blocker 400. In addition, the driving unit 490 may be mounted on the guide rail 150. The driving unit 490 may be any one of known motors providing a driving force. For example, the driving unit 490 may be a linear motor. Accordingly, the driving unit 490 may move along a lengthwise direction of the guide rail 150 and change the position of the ion blocker 400. A structure in which the position of the ion blocker 400 is changed is not limited thereto and may be changed in various ways.

According to the aforementioned example, the position of the ion blocker 400 can be more easily changed, so the ratio of radicals and ions acting on the substrate W can be efficiently adjusted even while treating the substrate W.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber having an inner space;
an ion blocker dividing the inner space into a first space at a bottom side and a second space at a top side;
a support unit configured to support a substrate at the first space; and
a plasma source generating a plasma at the inner space, and
wherein a plurality of passages are formed at the ion blocker for flowing a fluid from the second space to the first space, and
the ion blocker is made of a dielectric substance, and
an ion among an ion and a radical included in the plasma is captured while passing through the passage.

2. The substrate treating apparatus of claim 1, wherein the passage is a through hole which penetrates a top-bottom surface of the ion blocker.

3. The substrate treating apparatus of claim 1, wherein the ion blocker is formed of a mesh structure having the passage.

4. The substrate treating apparatus of claim 1, wherein a plurality of the ion blockers are equipped, and the plurality of ion blockers are disposed in a top-down direction spaced apart from each other.

5. The substrate treating apparatus of claim 4, wherein a passage formed at any one ion blocker among the plurality of ion blockers does not overlap with a passage formed at an adjacent ion blocker when seen from above.

6. The substrate treating apparatus of claim 1, further comprising a heating unit configured to transmit a heat source to a substrate supported on the support unit, and
wherein the heat source includes a light, a microwave, or a laser.

7. The substrate treating apparatus of claim 6, wherein a plasma source includes a coil surrounding an outer wall of the chamber and which applies a high frequency power, and
the heating unit is positioned at a top end of the chamber and transmits the heat source toward the ion blocker.

8. The substrate treating apparatus of claim 6, wherein the plasma source includes an electrode plate which is positioned at a top end of the chamber and applies a high frequency power, and
the support unit is grounded, and
the heating unit is positioned at a top side of the electrode plate.

9. The substrate treating apparatus of claim 8, wherein the electrode plate is made of a material including an Indium Tin Oxide (ITO) which lets the heat source pass through.

10. The substrate treating apparatus of claim 9, wherein a guide rail is installed at an inner sidewall of the chamber, and
a driving unit is installed at the ion blocker, and
the driving unit moves along the guide rail to change a position of the ion blocker.

11. The substrate treating apparatus of claim 1, wherein as an aspect ratio of a thickness of the ion blocker and a width of the passage increases, an amount of the ion captured by the ion blocker increases.

12. The substrate treating apparatus of claim 4, wherein as an interval between the plurality of ion blockers decreases, an amount of the ion which is captured by the ion blocker increases.

13. A substrate treating apparatus comprising:
an ion blocker which captures an ion included in a plasma; and
a support unit disposed at a bottom side of the ion blocker and configured to support a substrate, and
wherein the ion blocker is made of a dielectric substance.

14. The substrate treating apparatus of claim 13, wherein a plurality of through holes are formed at the ion blocker for flowing a fluid between a top space of the ion blocker and a bottom space of the ion blocker.

15. The substrate treating apparatus of claim 14, wherein a plurality of ion blockers are equipped, and the plurality of ion blockers are disposed in a top-down direction spaced apart from each other.

16. The substrate treating apparatus of claim 15, wherein a through hole formed at any one ion blocker among the plurality of ion blockers does not overlap with a through hole formed at an adjacent ion blocker when seen from above.

17. The substrate treating apparatus of claim 13, wherein the ion blocker is formed of a mesh structure.

18. The substrate treating apparatus of claim 13, further comprising a heat unit configured to transmit a heat source to a substrate supported on the support unit.

19. The substrate treating apparatus of claim 18, wherein the heating unit includes a lamp, a laser optical system, or a microwave generator.

20. A substrate treating apparatus comprising:
a chamber having an inner space;
an ion blocker dividing the inner space into a first space at a bottom side and a second space at a top side;
a support unit configured to support a substrate at the first space; and
a gas supply unit configured to supply a gas excited to a plasma at the second space;
a plasma source generating the plasma at the first space and/or the second space; and
a heating source passing through the ion blocker and transmitting a heat source to a substrate supported on the support unit, and
wherein the ion blocker is formed of a dielectric substance, and
a plurality of passages are formed at the ion blocker for flowing a fluid, and
an ion among an ion and a radical included in the plasma are captured while passing through the passage, and
the heating source passes through the ion blocker to be transmitted to the substrate supported on the support unit.
